(19) United States
(12) Patent Application Publication
(10) Pub. No.: US 2024/0395770 A1
(43) Pub. Date: Nov. 28, 2024

(54) METALLIC LID STRUCTURE FOR DISSIPATING HEAT GENERATED BY A THERMAL HOT SPOT REGION OF AN IC STRUCTURE

(71) Applicant: Taiwan Semiconductor Manufacturing Company, Ltd., Hsin-Chu (TW)

(72) Inventors: Po-Yao Lin, Hsinchu County (TW); Sing-Da Jiang, Hsinchu (TW); Tsunyen Wu, Hsinchu County (TW); Shih-Wei Liu, Hsinchu (TW); Kathy Wei Yan, Hsinchu (TW)

(21) Appl. No.: 18/467,412

(22) Filed: Sep. 14, 2023

Related U.S. Application Data
(60) Provisional application No. 63/504,247, filed on May 25, 2023.
(60) Provisional application No. 63/507,883, filed on Jun. 13, 2023.

(51) Int. Cl. H01L 25/065; H01L 23/00; H01L 23/373; H01L 23/42; H01L 23/48

(52) U.S. Cl. CPC H01L 25/0652; H01L 23/3736; H01L 23/42; H01L 23/481; H01L 23/562; H01L 24/08; H01L 24/80; H01L 2224/08145; H01L 2224/80895; H01L 2224/80896; H01L 2225/06589

(57) ABSTRACT

An Integrated Circuit (IC) structure includes a bottom level IC die and one or more top level IC dies. A first side of the one or more top level IC dies is bonded to the bottom IC die. A supporting substrate is coupled to a second side of the one or more top level IC dies. A plurality of conductive through-substrate vias (TSVs) each extend vertically through the supporting substrate. A metallic lid structure is disposed over the supporting substrate. The metallic lid structure is thermally coupled to the conductive TSVs.

### PRIORITY DATA

The present application is a utility application of provisional U.S. Patent Application No. 63/504,247, filed on May 25, 2023, and entitled “Metallic Lid Structure For Dissipating Heat Generated By A Thermal Hot Spot Region Of A Chip”, and U.S. provisional Application No. 63/507,883, filed on Jun. 13, 2023, and entitled “Metallic Lid Structure For Dissipating Heat Generated By A Thermal Hot Spot Region Of An Ic Structure” each of which are hereby incorporated herein by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

However, as semiconductor fabrication progresses to more advanced technology nodes, additional fabrication challenges may arise. For example, an IC chip may generate heat during its operation but may not be able to dissipate the heat quickly or effectively. As a result, the IC chip assembly may overheat, which may lead to IC device performance degradations or even failures. Therefore, more satisfactory heat dissipation solutions may be needed.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIGS. 1-5, 6A, 6C, 7A, and 8 illustrates various cross-sectional side views of an IC structure according to embodiments of the present disclosure.

FIGS. 6B-7B illustrates various planar top views of an IC structure according to embodiments of the present disclosure.

FIG. 9 illustrates an integrated circuit fabrication system according to various aspects of the present disclosure.

FIG. 10 is a flowchart illustrating a method of fabricating an IC structure according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to the implementation of a metallic lid structure (e.g., a copper lid structure) to quickly dissipate the heat generated by one or more thermal hot spot regions of an IC structure. In more detail, an IC structure may include one or more IC dies or IC chips. These IC dies or IC chips may contain electrical circuitry (comprised of transistors such as planar transistors, FinFET devices, or Gate-All-Around (GAA) devices) configured to perform various types of operations, such as processing computer instructions, storing data, transmit and/or receive electrical signals, detect radiation (e.g., visible light), sense biometric data, etc.

Thermal energy in the form of heat may be generated during the operations of the electrical circuitries, and some types of electrical circuitries may generate more heat than other types of electrical circuitries. When the heat-generation electrical circuitries are closely packed together on an IC die or IC chip, one or more thermal hotspot regions may be formed. These thermal hotspot regions may refer to regions or areas on an IC die or an IC chip where more heat is generated per unit area/volume per unit time than other regions of the IC die or IC chip. For example, a thermal hot spot region may have a greater temperature than a region that neighbors the thermal hot spot region during the operation of the IC die or IC chip. If the heat generated by the thermal hotspot regions is not quickly dissipated, then the performance of the IC die or IC chip may be degraded. For example, a computer processor (as a form of IC die or IC chip) may begin to slow down. As another example, an IC device may consume an excessive amount of power when it operates under an elevated temperature environment. In addition, the excessive amount of heat may shorten the lifespan or other degrade the durability of the IC die or IC chip. Therefore, a more satisfactory solution to quickly and efficiently dissipate the heat generated by the thermal hotspot regions may be needed.

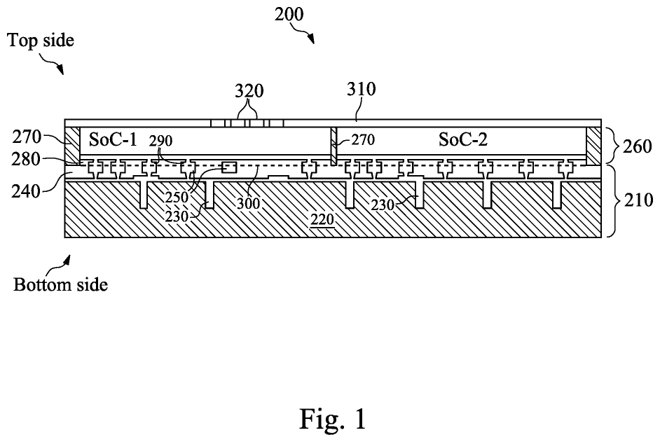

To address this problem, the present disclosure implements a metallic lid structure over the IC structure that contains the thermal hotspot regions. The metallic lid structure may include a metallic material with good thermal conductivity, such as copper. The metallic lid structure is thermally coupled with the IC structure through other materials that also have good thermal conductivity, such as through one or more metallization layers and a thermal interface material. Meanwhile, a plurality of thermally conductive through-substrate vias (TSVs) may be implemented in different regions of the IC structure (e.g., in a supporting substrate that is bonded to the IC dies or the IC chips of the IC structure). The implementation of the thermally conductive TSVs is configured such that each of the thermal hotspot regions of the IC structure is vertically aligned with a respective subset of the thermally conductive TSVs. In this manner, the heat generated by the thermally conductive region can be quickly transferred to the subset of the thermally conductive TSVs. The thermally conductive TSVs are thermally coupled to the metallic lid structure through the metallization layers and/or the thermal interface material. Accordingly, the TSVs may quickly transfer the heat generated by the thermal hotspot regions onto the metallic lid structure through the metallization layers and/or the thermal interface material. As a relatively big structure with a great amount of exposed surface material (compared to the rest of the components of the IC structure), the metallic lid structure can quickly and efficiently dissipate the heat generated by the thermal hotspot regions and transferred to the metallic lid structure through the thermally conductive TSVs, the metallization layers, and/or the thermal interface material. As a result, the device performance, reliability, and/or the lifespan of the IC structure herein can be improved. The various aspects of the present disclosure be discussed below with reference to FIGS. 1-5, 6A-7A, 6B-7B, and 8-9.

Referring now to FIG. 1, an IC structure 200 is provided. The IC structure 200 includes a bottom IC die 210. The bottom IC die 210 may include a System on an Integrated Chip (SoIC, also referred to as SoC), and as such, it may also be interchangeably referred to as a bottom SoIC die 210. The bottom IC die 210 includes a substrate 220. The substrate 220 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 220 may be a single-layer material having a uniform composition. Alternatively, the substrate 220 may include multiple material layers having similar or different compositions suitable for IC device manufacturing. In one example, the substrate 220 may be a silicon-on-insulator (SOI) substrate having a semiconductor silicon layer formed on a silicon oxide layer. In another example, the substrate 220 may include a conductive layer, a semiconductor layer, a dielectric layer, other layers, or combinations thereof. Various doped regions, such as source/drain regions, may be formed in or on the substrate 220. The doped regions may be doped with n-type dopants, such as phosphorus or arsenic, and/or p-type dopants, such as boron, depending on design requirements. The doped regions may be formed directly on the substrate 220, in a p-well structure, in an n-well structure, in a dual-well structure, or using a raised structure. Doped regions may be formed by implantation of dopant atoms, in-situ doped epitaxial growth, and/or other suitable techniques. The bottom IC die 210 may include electrical circuitry that is formed partially within or on the substrate 220. The electrical circuitry may include planar transistors or three-dimensional transistors such as FinFET devices or multi-channel gate-all-around (GAA) devices.

The bottom IC die 210 includes a plurality of conductive vias 230 that extend vertically through the substrate 220 at least partially. The conductive vias 230 may be formed by etching via openings in the substrate 220, for example, using one or more wet etching or dry etching processes, and then filling the etched via openings with a conductive material, such as tungsten, cobalt, copper, ruthenium, aluminum, or combinations thereof. In some embodiments, the conductive vias 230 may include through-substrate vias (TSVs).

The bottom IC die 210 also includes a dielectric layer 240 that is formed over the substrate 220. The dielectric layer 240 may be formed using a suitable deposition technique, such as chemical vapor deposition (CVD), physical vapor deposition (PVD), atomic layer deposition (ALD), or combinations thereof. In some embodiments, the dielectric layer 240 includes silicon oxide (e.g., SiO₂).

The bottom IC die 210 further includes a plurality of bonding pads 250. The bonding pads 250 may include a conductive material such as copper, aluminum, tungsten, cobalt, ruthenium, or combinations thereof. The bonding pads 250 are embedded in the dielectric layer 240, and they may be electrically coupled to the electrical circuitry of the bottom IC die 210 through conductive vias. It is understood that the bonding pads 250 may be configured to provide electrical connectivity between the electrical circuitry of the bottom IC die 210 and other devices that are external to the bottom IC die 210.

The IC structure 200 further includes one or more top IC dies 260. For example, in the illustrated embodiment of FIG. 1, two IC dies—SoC die 1 (labeled as SoC-1 herein) and SoC die 2 (labeled as SoC-2 herein)—are implemented as the top IC dies 260. The SoC die 1 and the SoC die 2 may each include electrical circuitry that is implemented using planar transistors or three-dimensional transistors such as FinFET devices or multi-channel GAA devices.

The top IC dies 260 may be located over a top side of the bottom IC die 210 vertically. In the embodiment shown in FIG. 1, each of the IC dies of the top IC dies 260 may have smaller dimensions (or a smaller horizontal footprint) than the bottom IC die 210. As such, filler materials 270 may be disposed around, and between, the SoC die 1 and the SoC die 2 of the top IC dies 260. In some embodiments, the filler materials 270 may include an electrically insulating material, such as silicon oxide (SiO₂). The filler material 270 between the SoC die 1 and the SoC die 2 may help maintain the proper electrical isolation between the SoC die 1 and the SoC die 2, for example, so that they do not short into one another electrically. The filler material 270 disposed on the side surfaces of the SoC die 1 and the SoC die 2 facing outwards may also protect the SoC die 1 and the SoC die 2 from external contaminant sources and/or objects that can cause mechanical or physical damage to the SoC die 1 or the SoC die 2.

The top IC dies 260 may also include a dielectric layer 280 that is formed on bottom surfaces of the SoC die 1 and the SoC die 2 (e.g., the surfaces facing the bottom side, or in other words, toward the bottom IC die 210). The dielectric layer 280 may be formed using a suitable deposition technique, such as CVD, PVD. ALD, or combinations thereof. In some embodiments, the dielectric layer 280 includes silicon oxide.

The top IC dies 210 further include a plurality of bonding pads 290. The bonding pads 290 may include a conductive material such as copper, aluminum, tungsten, cobalt, ruthenium, or combinations thereof. The bonding pads 290 are embedded in the dielectric layer 280, and they may be electrically coupled to the electrical circuitry of the top IC dies 260 (e.g., to either or both of the SoC die 1 or the SoC die 2) through conductive vias. It is understood that the bonding pads 290 may be configured to provide electrical connectivity between the electrical circuitry of the top IC dies 260 and other devices that are external to the top IC dies 260.

The top IC dies 260 may be bonded to the bottom IC die 210 through a bonding interface 300. The bonding interface 300 may be formed between the top side surface of the dielectric layer 240 and the bottom side surface of the dielectric layer 280, and between the top side surfaces of the bonding pads 250 and the bottom side surfaces of the bonding pads 290. In some embodiments, a hybrid bonding process may be used to bond the top IC dies 260 to the bottom IC die 210. Since the bonding pads 250 are bonded to the bonding pads 290, the electrical circuitry of the bottom IC die 210 may be electrically coupled to the electrical circuitry of the top IC dies 260.

A dielectric layer 310 is formed over the top surfaces of the top IC dies 260. The dielectric layer 310 may be formed using a suitable deposition technique, such as CVD, PVD, ALD, or combinations thereof. In some embodiments, the dielectric layer 310 includes silicon oxide. A plurality of bonding pads 320 are formed to be embedded in the dielectric layer 310. For example, one or more etching processes may be performed to etch openings in the dielectric layer 310. These openings are subsequently filled with a conductive material such as copper, aluminum, tungsten, cobalt, ruthenium, or combinations thereof. A planarization process, such as a chemical mechanical polishing (CMP) process, may be performed to planarize the upper surfaces of the conductive materials filling the openings. The bonding pads 320 may also be configured to provide electrical connectivity to the electrical circuitry of the top IC dies 260. And since the electrical circuitry of the top IC dies 260 is electrically coupled to the electrical circuitry of the bottom IC die 210 through the bonding pads 290 and 250, it is understood that the bonding pads 320 may also be used to gain electrical access to the electrical circuitry of the bottom IC die 210.

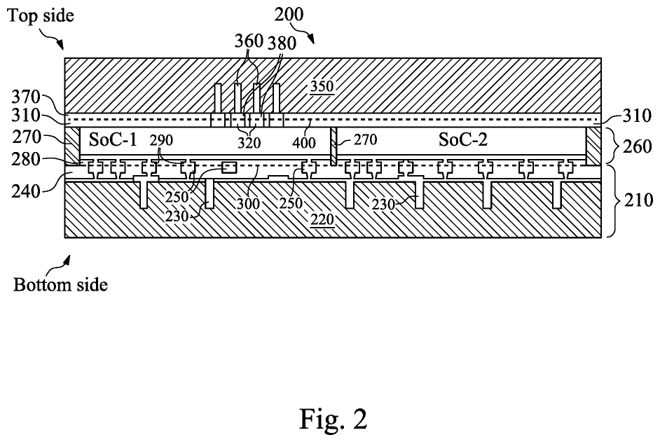

Referring now to FIG. 2, a supporting substrate 350 is bonded to the top IC dies 260. In some embodiments, the supporting substrate 350 may include a bulk silicon material. It is understood that the supporting substrate 350 may provide mechanical rigidity and/or structural support for the top IC dies 260 and the bottom IC die 210. The supporting substrate 350 may include a plurality of TSVs 360 that each extend at least partially through the supporting substrate 350 vertically. The TSVs 360 may each include one or more conductive materials, such as tungsten, cobalt, copper, ruthenium, aluminum, or combinations thereof. These TSVs 360 may be formed by etching opening into the supporting substrate 350 from the bottom side (where the etched openings extend toward the top side), filling the etched openings with the one or more conductive materials, and subsequently performing a CMP process to remove excess portions of the conductive materials outside the openings.

A dielectric layer 370 is formed on the bottom surface of the supporting substrate 350. The dielectric layer 370 may be formed using a suitable deposition technique, such as CVD, PVD, ALD, or combinations thereof. In some embodiments, the dielectric layer 370 includes silicon oxide. A plurality of bonding pads 380 are formed to be embedded in the dielectric layer 370. For example, one or more etching processes may be performed to etch openings (from the bottom side) in the dielectric layer 370. These openings are subsequently filled with a conductive material such as copper, aluminum, tungsten, cobalt, ruthenium, or combinations thereof. A planarization process, such as a CMP process, may be performed to planarize the surfaces of the conductive materials filling the openings, until the conductive materials filling the openings have substantially co-planar surfaces with the dielectric layer 370. In this manner, the bonding pads 380 are formed. Note that the locations of the bonding pads 380 are configured to be vertically aligned with the TSVs 360, respectively.

The supporting substrate 350 may be bonded to the top IC dies 260 through a bonding interface 400. The bonding interface 400 may be formed between the top side surface of the dielectric layer 310 and the bottom side surface of the dielectric layer 370, and between the top side surfaces of the bonding pads 320 and the bottom side surfaces of the bonding pads 380. In some embodiments, a hybrid bonding process may be used to bond the supporting substrate 350 to the top IC dies 260. It is understood that the bonding pads 380 and the TSVs 360 may be utilized to dissipate heat generated by thermal hot spot regions of the top IC dies 260 and/or the bottom IC die 210.

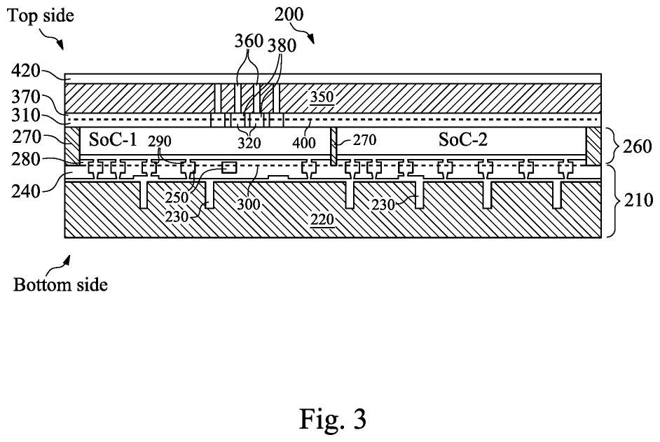

Referring now to FIG. 3, a thinning process is performed to reduce a thickness of the supporting substrate 350 from the top side. The thinning process may include one or more mechanical grinding and/or chemical etching processes in some embodiments. The thinning process may be performed until the TSVs 360 are exposed to the top side. Thereafter, a metallization structure 420 is formed on the top side of the supporting substrate 350. In some embodiments, the metallization structure 420 may include one or more layers of a thermally conductive material, such as copper, aluminum, etc. Since the metallization structure 420 is thermally coupled to the TSVs 360 (e.g., in direct physical contact), the thermally conductive material of the metallization structure 420 helps spread the heat from the TSVs (e.g., heat generated by the thermal hotspot regions from the bottom IC die 210 or the top IC dies 260).

In some other embodiments, the metallization structure 420 is a multilayer interconnect (MLI) structure that could provide electrical connectivity to various devices (for example, transistors, resistors, capacitors, and/or inductors) and/or components (for example, gate structures and/or source/drain features) of the top IC dies 260 or the bottom IC die 210. For example, the metallization structure 420 may include a combination of dielectric layers and electrically conductive layers (for example, metal layers, such as nickel, gold, aluminum, etc.) configured to form various interconnect structures. The conductive layers are configured to form vertical interconnect features (providing, for example, vertical connection between features and/or vertical electrical routing), such as contacts and/or vias, and/or horizontal interconnect features (providing, for example, horizontal electrical routing), such as conductive lines. Vertical interconnect features typically connect horizontal interconnect features in different layers (or different planes) of the metallization structure 420. During operation, the MLI structure routes signals between the devices and/or the components of the top IC dies 260 and/or the bottom IC die 210 and/or distribute signals (for example, clock signals, voltage signals, and/or ground signals) to the devices and/or the components of the top IC dies 260 and/or the bottom IC die 210.

It is understood that regardless of whether the metallization structure 420 is implemented as including a single interconnect layer in some embodiments or multiple interconnect layers in some other embodiments or, it is illustrated as a single layer structure in FIG. 3 herein for reasons of simplicity. It is also understood that the metallization structure 420 may be interchangeably referred to as a back-side metallization structure 420, since it is formed on the back side of the supporting substrate 350 (or over the back side of the top IC dies 260).

Again, even when the metallization structure 420 is implemented as a multilayer interconnect structure, it is still capable of dissipating heat in addition to being capable of routing electrical signals. For example, the metal lines and/or the vias of the various metal layers of metallization structure 420 are capable of receiving, transferring, and/or dissipating the heat generated by the top IC dies 260 and/or the bottom IC die 210, where such heat is transferred to the metallization structure 420 at least in part through the bonding pads 320, the bonding pads 380, and the TSVs 360.

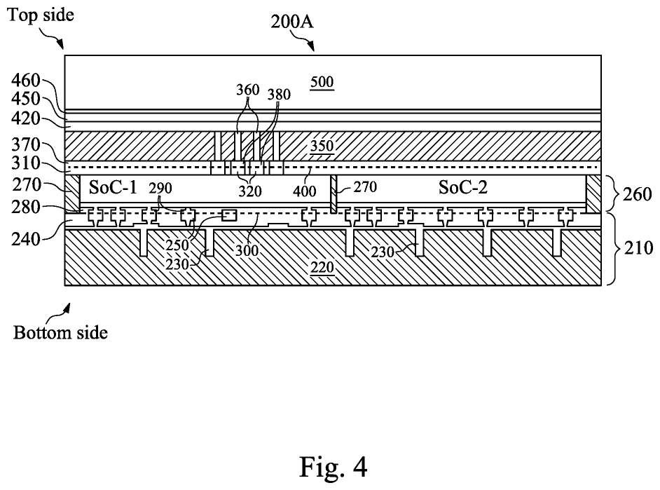

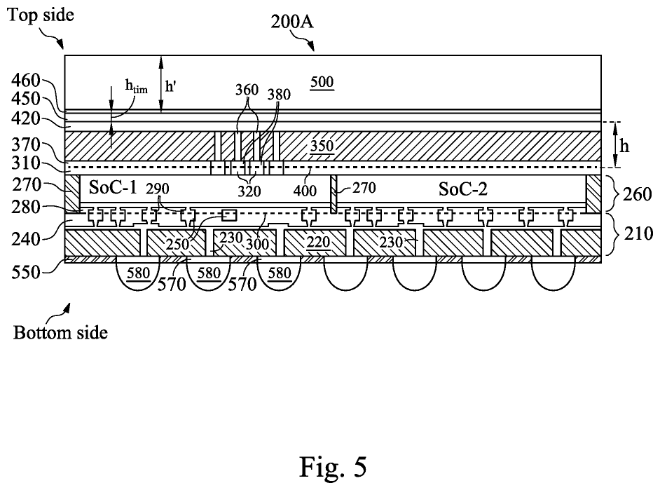

It is understood that the processes performed in FIGS. 1-3 are wafer level processes. In other words, the IC structure 200 shown in FIGS. 1-3 is still a wafer level structure (e.g., no wafer singulation process has been performed yet). Thus, the bottom IC die 210 may actually include a plurality of IC dies on a wafer in some embodiments, though the multiple IC dies of the bottom IC die 210 are not specifically illustrated herein for reasons of simplicity. In FIGS. 4-5 discussed below, however, the IC structure 200 is a chip level structure. In other words, following the completion of the fabrication processes of FIG. 3, and before the performance of the fabrication processes of FIG. 4, the wafer level IC structure 200 is singulated into a plurality of chip level structures, hereinafter referred to as an IC chip assembly 200A.

Referring now to FIG. 4, a thermal interface material (TIM) 450 is formed over the top side of the metallization structure 420. In some embodiments, the TIM 450 includes a solder material. The solder material may include a metal alloy material that is meltable under a hot temperature. For example, the metal alloy material may be made of tin and/or lead, and it may melt under a hot iron when the hot iron reaches a temperature of about 600 degrees Fahrenheit or greater. The TIM 450 is a good candidate for facilitating heat dissipation.

Thereafter, a metallization structure 460 is optionally formed over the TIM 450. The metallization structure 460 may be configured similar to the metallization structure 420. For example, the metallization structure 460 may include a single layer of thermally conductive material that is configured to facilitate heat dissipation, or it may include a plurality of interconnect layers as a part of an interconnect structure (e.g., including a plurality of metal lines and vias) capable of routing electrical signals and/or dissipating heat.

A metallic lid structure 500 is then attached to the TIM 450 over the top side through the metallization structure 460. In some embodiments, the metallic lid structure includes a single block of thermally conductive metallic material, such as copper. In other embodiments, the metallic lid structure 500 may include a plurality of metallic layers, which may include different material compositions. In yet other embodiments, the metallic lid structure 500 may include a thermally conductive material other than copper. In some embodiments, the metallization structure 460 may be formed on the bottom side of the metallic lid structure 500 first, and then the metallic lid structure 500 (with the metallization structure 460 at its bottom side) is attached to the top side of the TIM 450. Regardless of when the metallization structure 460 is formed (or whether it is formed at all), it is understood that a thermal reflow process may be performed to facilitate the attachment of the metallic lid structure 500 to the components therebelow. For example, the thermal reflow process may transform the TIM 450 into a liquid-like state, which allows it to better facilitate the bonding of the components above and the components below.

Referring now to FIG. 5, a thinning process is performed to reduce a thickness of the substrate 220 of the bottom IC die 210 from the bottom side. In some embodiments, before the thinning process is performed, the IC chip assembly 200A may be flipped over (e.g., flipped vertically). The thinning process may include one or more mechanical grinding and/or chemical etching processes in some embodiments. The thinning process may be performed until the TSVs 230 are exposed to the bottom side. Thereafter, a passivation layer 550 may be formed over the substrate 220 on the bottom side. In some embodiments, the passivation layer 550 is formed by a suitable deposition process, such as a CVD process. The passivation layer 550 may serve to protect the components of the IC chip assembly 200A, for example, from exposure to contaminant particles, moisture, oxygen, etc. The passivation layer 550 may include a dielectric layer in some embodiments. For example, the passivation layer 550 may include silicon oxide.

Once the passivation layer 550 is formed, one or more etching processes may be performed to form a plurality of openings in the passivation layer 550. A subset of the openings may be vertically aligned with the TSVs 230. In other words, the subset of the openings may expose the TSVs 230 to the bottom side. Meanwhile, other ones of the openings in the passivation layer 550 may not be vertically aligned with the TSVs 230 but may expose regions of the substrate 220 instead. Regardless of where these openings are formed, they are subsequently filled with a conductive material. In some embodiments, the conductive material may include copper, aluminum, tungsten, cobalt, ruthenium, gold, nickel, tin, or combinations thereof. A planarization process, such as a CMP process, may be performed to planarize the bottom side surfaces of the conductive materials filling the openings with the bottom surface of the passivation layer 550. As such, the portions of the conductive materials filling these openings form under bump metallization (UBM) 570.

After the formation of the UBM 570, conductive bumps 580 are formed over the bottom side of the UBM 570. In some embodiments, a conductive bump 580 is formed for each respective UBM 570. In some embodiments, the conductive bumps 580 may be formed as a ball grid array (BGA). The conductive bumps 580 are formed to each contain a conductive material, for example, tin. The conductive bumps 580 may serve as electrical access points for the IC component (e.g., the electrical circuitry) of the IC chip assembly 200A.

At this stage of fabrication, the supporting substrate 350 has a thickness h that is measured from a top side surface of the metallization structure 420 to the interface 400. The TIM 450 has a thickness hₜᵢₘ that is measured from a top side surface of the TIM 450 to a bottom side surface of the TIM 450. The metallic lid structure 500 has a thickness h′ that is measured from a top side surface of the metallic lid structure 500 to a bottom side surface of the metallization structure 460 in embodiments where the metallization structure 460 was formed. In embodiments where the metallization structure 460 was not formed, the thickness h′ is measured from the top side surface of the metallic lid structure 500 to the bottom side surface of the metallic lid structure 500. In some embodiments, a sum H of the thicknesses h, hₜᵢₘ, and h′ is less than about 31 mils (where 1 mil= 1/1000 of an inch, or about 787 microns). In other words, H=h+hₜᵢₘ+h′<=31 mils.

In some embodiments, the sum H is substantially equal to an originally specified thickness of the supporting substrate 350. For example, a client (e.g., an IC design house) may have specified a dimension or thickness H for a supporting substrate similar to the supporting substrate 350. Upon receiving such a specification, the thickness of the supporting substrate 350 may be reconfigured to be h instead, so that the overall sum of h (the thickness of the supporting substrate 350), the hₜᵢₘ (the thickness of the TIM 450), and h′ (the thickness of the metallic lid structure 500) may still be equal to H. In this manner, the overall dimension of the IC chip assembly 200A remains substantially the same as the overall dimension specified by the client. Stated differently, the thickness h of the supporting substrate 350 is reduced (e.g., from H to h) to account for the added thicknesses of hₜᵢₘ (of the TIM 450) and h′ (of the metallic lid structure 500).

In some embodiments, a ratio of h′ and h is less than about 1 but greater than about 0.34. In other words, 1>=h′/h>=0.34. Such a ratio range helps to optimize device performance. For example, if the above ratio of h′ and h is greater than 1, that would mean that the metallic lid structure 500 is too thick compared to the supporting substrate 350. When this happens, the supporting substrate 350 may not be thick enough to provide a sufficient amount of rigidity and/or mechanical support for the components bonded to the supporting substrate 350, such as the top IC dies 260 and/or the bottom IC die 210. On the other hand, if the above ratio of h′ and h is less than 0.34, that would mean the metallic lid structure 500 is too thin compared to the supporting substrate 350. When this happens, the metallic lid structure 500 may not be capable of quickly dissipating the heat generated by the thermal hot spot regions, which would still lead to degraded device performance and/or reduced lifespan of the IC chip assembly 200A. Here, the ratio range of 1>=h′/h>=0.34 ensures that the supporting substrate 350 is thick enough to provide the sufficient amount of rigidity and/or mechanical strength for the top IC dies 260 and/or the bottom IC die 210, while also ensuring that the metallic lid structure 500 is sufficiently thick to allow heat generated by the thermal hot spot regions to be quickly dissipated.

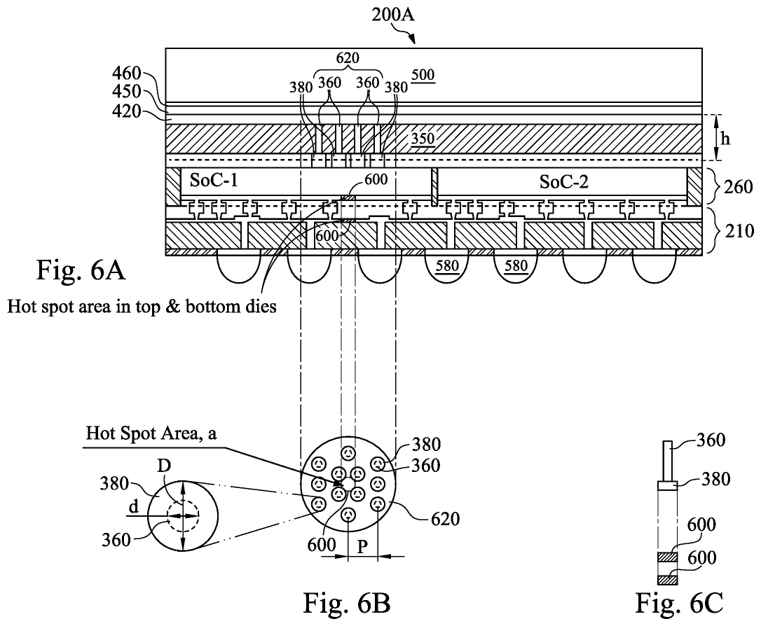

FIG. 6A is a diagrammatic cross-sectional side view of the IC chip assembly 200A, and FIG. 6B is a planar top view of a portion of the IC chip assembly 200A. In more detail, the planar top view FIG. 6B illustrates the portion of the IC chip assembly 200A that includes a thermal hot spot region 600 and a TSV enclosure area 620. The thermal hot spot regions 600 are also shown in the cross-sectional side view of FIG. 6A. For example, one of the thermal hot spot regions 600 may be located in the SoC die 1 of the top IC dies 260, and another one of the thermal hot spot regions 600 may be located in the bottom IC die 210. Each of the thermal hot spot regions 600 may correspond to, or include, electrical circuitry within the top IC dies 260 or the bottom IC die 210, where the electrical circuitry may generate a large amount of heat. For example, the heat generated by the electrical circuitry may cause the thermal hot spot regions 600 to have an elevated temperature compared to other regions of the top IC dies 260 and/or other regions of the bottom IC die 210 that neighbor the thermal hot spot regions 600. If the heat is not quickly and/or efficiently dissipated, then the device performance and/or lifespan of the IC chip assembly 200A may be adversely impacted.

According to various aspects of the present disclosure, the metallic lid structure 500 and the TSVs 360 and the bonding pads 380 are configured to optimize the dissipation of heat generated by the thermal hot spot regions 600. For example, the locations of the TSVs 360 and/or the bonding pads 380 are configured such that they are vertically aligned with the thermal hot spot regions 600. For example, the location of the thermal hot spot regions 600 may be vertically aligned with a center or a centroid of the TSVs 360 or a center or a centroid of the bonding pads 380. An example of this vertical alignment is shown in FIG. 6C, which is a more magnified cross-sectional view of a portion of the IC chip assembly 200A. For reasons of simplicity, components other than the TSVs 360, the bonding pads 380, or the thermal hot spot regions 600 are not specifically illustrated in FIG. 6C. In any case, such a vertical alignment helps ensure that the heat generated by the thermal hot spot regions 600 can propagate to the TSVs 360 and the bonding pads 380 through a shortest possible path. As such, the heat generated by the thermal hot spot regions 600 can be quickly and efficiently dissipated through the bonding pads 380, through the TSVs 360, and eventually through the metallic lid structure 500, since the metallic lid structure 500 is thermally coupled to the TSVs 360 and the bonding pads 380 through the TIM 450 and through the metallization structure 420, and through the metallization structure 460 if the metallization structure 460 has been optionally implemented. Note that since the TSVs 360 are implemented herein for heat dissipation, rather than electrical connection, no conductive pads are needed between the TSVs 360 and the metallization structure 420. In addition, the bonding pads 380 may be omitted in some embodiments as well.

As shown in the planar top view of FIG. 6B, the TSV enclosure area 620 may have a circular shape in the top view. In some embodiments, an area of the circular TSV enclosure area 620 may be represented by “A”. The thermal hot spot region 600 may have a substantially rectangular shape. In some embodiments, an area of the rectangular shape of the thermal hot spot region 600 may be represented by “a”. In some embodiments, a ratio of the TSV enclosure area 620 area “A” and the thermal hot spot region 600 area “a” is greater than about 1.2. In other words, A/a>=1.2. Such a ratio also helps to ensure that a sufficient large number of TSVs 360 have been implemented above the thermal hot spot regions 600, and that the TSV enclosure area 620 may be large enough to cover the thermal hot spot region 600 to facilitate the dissipation of heat generated by the thermal hot spot regions 600.

A magnified portion of a top view of an individual bonding pad 380 and an individual TSV 360 is also illustrated in FIG. 6B. The bonding pad 380 may have a substantially circular top view shape, and it may have a diameter “D”. Similarly, the TSV 360 may also have a substantially circular top view shape, and it may have a diameter “d”. The TSV 360 has a smaller area than the bonding pad 380, and this is represented by the fact that the diameter d is smaller than the diameter D. In some embodiment, a ratio of the diameter “D” and the diameter “d” is greater than about 1.1. In other words, D/d>=1.1.

As shown in FIG. 6B, a distance between adjacent ones of the TSVs 360 is represented by P. In some embodiments, a ratio of the distance P and the diameter D is greater than about 0 but less than about 4. In other words, 0<=P/D<=4. Such a ratio range helps ensure that the TSVs 360 are spaced apart sufficiently, and that each of the bonding pads 380 is also large enough (e.g., having a sufficient horizontal area) to effectively dissipate the heat generated by the thermal hot spot regions 600.

In some embodiments, a ratio of the height “h” of the supporting substrate 350 and the diameter “d” is greater than about 4 but less than about 8. In other words, 8>=h/d>=4. Such a ratio range ensures that the TSVs 360 can be easily fabricated. If the ratio of h/d is too high, that may lead to an excessively high aspect ratio of the TSVs 360, meaning that the TSV openings would have to be etched long and thin, which may lead to fabrication difficulties. If the ratio of h/d is too low, then that may indicate that the supporting substrate 350 had not been made sufficiently thick to provide the structural rigidity and/or mechanical support it is meant to have. Here, the ratio range of h/d ensures the ease of fabrication of the TSVs 360, as well as the performance of the supporting substrate 350.

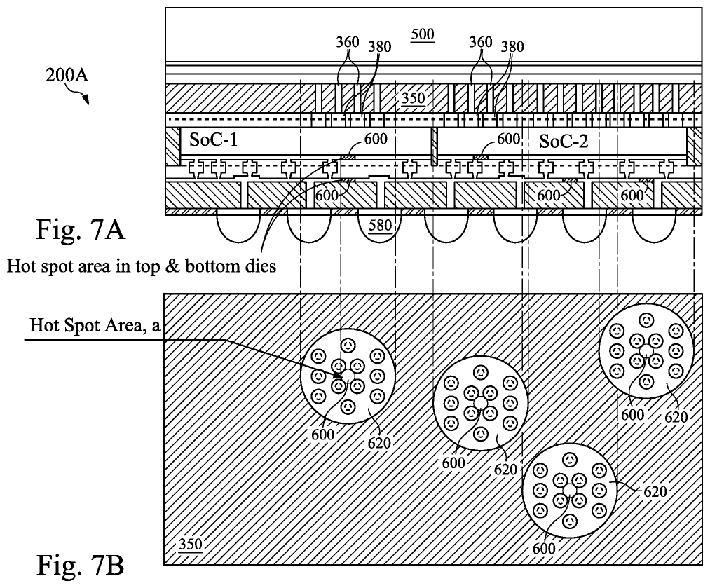

FIGS. 7A and 7B are a diagrammatic cross-sectional side view and a planar top view of portions of the IC chip assembly 200A according to another embodiment. In more detail, the planar top view FIG. 7B illustrates the portions of the IC chip assembly 200A that includes a plurality of thermal hot spot regions 600 and a plurality of TSV enclosure areas 620. The multiple thermal hot spot regions 600 are also shown in the cross-sectional side view of FIG. 7A. For example, two of the thermal hot spot regions 600 may be located in the top IC dies 260 (e.g., one in the SoC die 1, and another in the SoC die 2), and three of the thermal hot spot regions 600 may be located in the bottom IC die 210.

The locations of the TSVs 360 and/or the bonding pads 380 are configured such that they are vertically aligned with the thermal hot spot regions 600, respectively. For example, each of the thermal hot spot regions 600 has a corresponding subset of the TSVs 360 and a corresponding subset of the bonding pads 380 vertically aligned therewith. The vertical alignment helps ensure that the heat generated by the thermal hot spot regions 600 can be quickly and efficiently dissipated through the shortest path that includes the bonding pads 380, through the TSVs 360, and eventually through the metallic lid structure 500, since the metallic lid structure 500 is thermally coupled to the TSVs 360 and the bonding pads 380 through the TIM 450 and through the metallization structure 420, and through the metallization structure 460 if the metallization structure 460 has been optionally implemented.

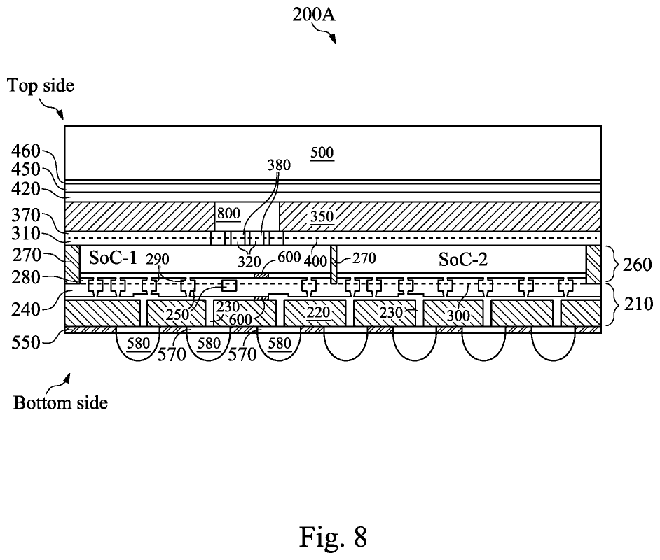

FIG. 8 is a cross-sectional side view of another embodiment of the IC chip assembly 200A. Again, similar components appearing in FIGS. 1-7 will be labeled the same in FIG. 8. One difference between the embodiment of FIG. 8 and the embodiments discussed above is that the embodiment of FIG. 8 does not utilize the TSVs 360 to dissipate heat. Instead, the embodiment of FIG. 8 implements a heat conductive block 800 in place of the TSVs 360. For example, the heat conductive block 800 may be formed using the same fabrication processes that were used to form the TSVs 360, and it may have the same material composition as the TSVs 360. However, compared to the TSVs 360, the heat conductive block 800 may have a larger horizontal dimension. In other words, the heat conductive block 800 may be wide enough to encompass multiple ones of the TSVs 360. As shown in FIG. 8, the heat conductive block 800 is still disposed over, and thermally coupled to, the thermal hotspot regions 600A. For example, the heat generated by the thermal hotspot regions 600A may be transmitted to the heat conductive block 800 through the bonding pads 320 and 380, and the heat conductive block 800 may then transmit the heat to the metallic lid structure 500 for dissipation outside the IC chip assembly 200A. It is understood that the bonding pads 320 and/or 380 may or may not be implemented in alternative embodiments, since the heat conductive pad 800 herein is implemented to dissipate heat, rather than for electrical connection. As such, the bonding pads 320 and/or 380 may not be needed for electrical connection and could therefore be omitted in some embodiments.

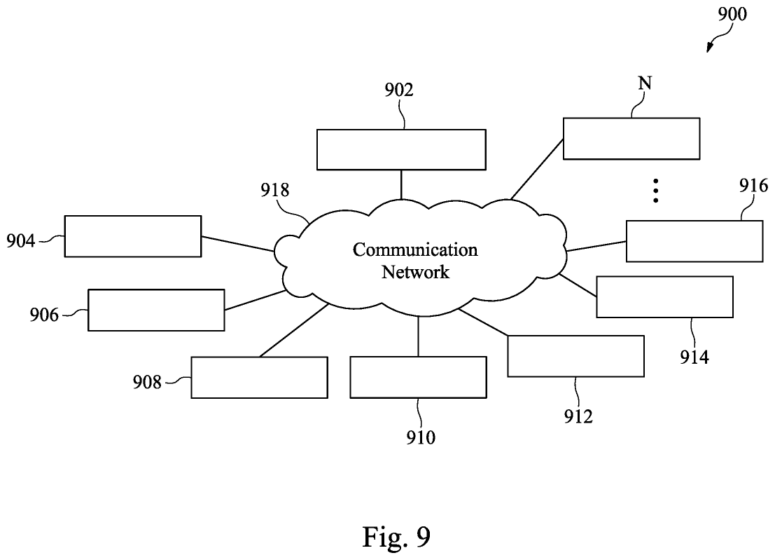

FIG. 9 illustrates an integrated circuit fabrication system 900 that can be utilized to fabricate the IC structure 200 and/or the IC chip assembly 200A according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such the processing tools to perform the various deposition processes discussed above; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

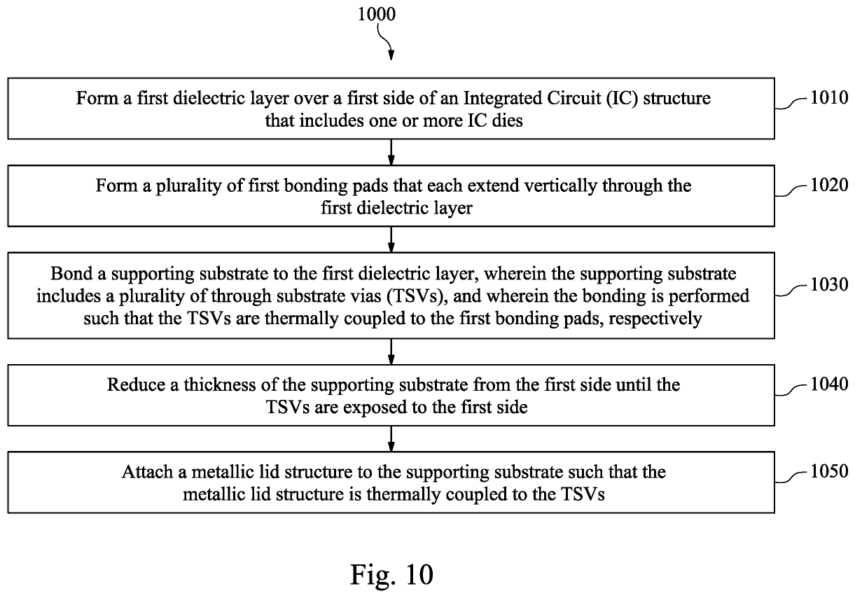

FIG. 10 is a flowchart illustrating a method 1000 according to an embodiment of the present disclosure. The method 1000 includes a step 1010 to form a first dielectric layer over a first side of an Integrated Circuit (IC) structure that includes one or more IC dies.

The method 1000 includes a step 1020 to form a plurality of first bonding pads that each extend vertically through the first dielectric layer.

The method 1000 includes a step 1030 to bond a supporting substrate to the first dielectric layer. The supporting substrate includes a plurality of through substrate vias (TSVs). The bonding is performed such that the TSVs are thermally coupled to the first bonding pads, respectively.

The method 1000 includes a step 1040 to reduce a thickness of the supporting substrate from the first side until the TSVs are exposed to the first side.

The method 1000 includes a step 1050 to attach a metallic lid structure to the supporting substrate such that the metallic lid structure is thermally coupled to the TSVs.

In some embodiments, the IC structure includes one or more thermal hot spot regions. In some embodiments, the bonding is performed such that each of the one or more thermal hot spot regions is vertically aligned with a respective subset of the TSVs.

In some embodiments, the IC structure includes electrical circuitry, and a plurality of conductive bumps is formed over a second side of the IC structure opposite the first side. The conductive bumps are electrically coupled to the electrical circuitry of the IC structure. In some embodiments, the IC structure is a wafer level IC structure, and the wafer level IC structure is singulated before the metallic lid structure is attached.

In some embodiments, the IC structure includes a bottom IC die and one or more top IC dies that are electrically coupled to the bottom IC die.

It is understood that additional processes may be performed before, during, or after the steps 1010-1050 of the method 1000. For example, the method 1000 may include a step that is performed after the thickness of the supporting substrate has been reduced but before the metallic lid structure has been attached. The step may include forming a first metallization structure over the supporting substrate, such that the TSVs are thermally coupled to the first metallization structure. The method 1000 may also include a step of forming a thermal interface material (TIM) over the first metallization structure. The TIM is located between the first metallization structure and the metallic lid structure after the metallic lid structure has been attached. In some embodiments, a second metallization structure is formed on a second side of the metallic lid structure opposite the first side, and the attaching of the metallic lid structure includes attaching the second metallization structure to the TIM. As another example, the method 1000 may include the following steps: forming a second dielectric layer over the supporting substrate, and forming a plurality of second bonding pads in the second dielectric layer. In some embodiments, the second bonding pads are thermally coupled to the TSVs, and the bonding is performed such that the first bonding pads are bonded to the second bonding pads. For reasons of simplicity, other additional steps are not discussed herein in detail.

In summary, the present disclosure involves implementing a thermally conductive lid structure (e.g., a copper lid structure) and a plurality of TSVs to efficiently dissipate heat generated by one or more thermal hot spot regions of an IC structure. By doing so, the present disclosure offers advantages over other IC packages. It is understood, however, that other embodiments may offer additional advantages, and not all advantages are necessarily disclosed herein, and that no particular advantage is required for all embodiments. One advantage is improved device performance. In more detail, the IC structure may include one or more IC dies that contain electrical circuitries, where the heat generated by some of the electrical circuitries may result in thermal hot spot regions having elevated temperatures compared to a rest of the IC structure. If the heat is not quickly dissipated, it may lead to device performance degradations and/or shortened lifespan of the IC structure. Here, the TSVs may be vertically aligned with the thermal hot spot regions and thermally coupled to the thermally conductive lid structure. In this manner, a short path between the thermal hot spot regions and the thermally conductive lid structure may be established, and the thermally conductive lid structure may be able to quickly dissipate the heat generated by the thermal hot spot regions. As a result, the IC structure may operate in a cooler environment overall, which improves device performance (e.g., faster speed or lower power consumption). Another advantage is a longer lifespan of the IC structure. In that regard, when an IC structure operates in an environment with elevated temperatures for an extended period of time, it may have a reduced lifespan. Here, the quick and efficient thermal dissipation enabled by the TSVs and the thermally conductive lid structure may prevent (or at least reduce) the operation of the IC structure in an elevated temperature environment. Accordingly, the lifespan of the IC structure of the present disclosure may be prolonged. Other advantages include compatibility with existing fabrication and/or packaging processes, so the present disclosure does not require additional processing and is therefore easy and cheap to implement.

One aspect of the present disclosure involves an Integrated Circuit (IC) structure. The IC structure includes a bottom level IC die and one or more top level IC dies. A first side of the one or more top level IC dies is bonded to the bottom IC die. A supporting substrate is coupled to a second side of the one or more top level IC dies. A plurality of conductive through-substrate vias (TSVs) each extend vertically through the supporting substrate. A metallic lid structure is disposed over the supporting substrate. The metallic lid structure is thermally coupled to the conductive TSVs.

Another aspect of the present disclosure involves an Integrated Circuit (IC) structure. The IC structure includes one or more integrated circuit (IC) dies. During an electrical operation of the one or more IC dies, a first region of the one or more IC dies has a greater temperature than a second region of the one or more IC dies that neighbors the first region. A substrate is disposed over the one or more IC dies. The substrate includes a plurality of through substrate vias (TSVs). A location of the TSVs is vertically aligned with a location of the first region of the one or more IC dies. A thermally conductive lid structure is disposed over the substrate. The thermally conductive lid structure is configured to dissipate thermal energy generated from the first region of the one or more IC dies at least in part through the TSVs.

Yet another aspect of the present disclosure involves a method. A first dielectric layer is formed over a first side of an Integrated Circuit (IC) structure that includes one or more IC dies. A plurality of first bonding pads is formed, where the first bonding pads each extend vertically through the first dielectric layer. A supporting substrate is bonded to the first dielectric layer. The supporting substrate includes a plurality of through substrate vias (TSVs). The bonding is performed such that the TSVs are thermally coupled to the first bonding pads, respectively. A thickness of the supporting substrate is reduced from the first side until the TSVs are exposed to the first side. A metallic lid structure is attached to the supporting substrate such that the metallic lid structure is thermally coupled to the TSVs.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A structure, comprising:
a bottom level integrated circuit (IC) die;
one or more top level IC dies, wherein a first side of the one or more top level IC dies is bonded to the bottom IC die;
a supporting substrate coupled to a second side of the one or more top level IC dies;
a plurality of conductive through-substrate vias (TSVs) that each extend vertically through the supporting substrate; and
a metallic lid structure disposed over the supporting substrate, wherein the metallic lid structure is thermally coupled to the conductive TSVs.

2. The structure of claim 1, wherein the supporting substrate includes a silicon substrate.

3. The structure of claim 1, wherein:
the bottom level IC die or the one or more top level IC dies include a thermal hot spot region that has an elevated temperature compared to a rest of the bottom level IC die or a rest of the one or more top level IC dies; and
the TSVs are vertically aligned with the thermal hot spot region.

4. The structure of claim 3, wherein:
the bottom level IC die or the one or more top level IC dies include a plurality of thermal hot spot regions;
the plurality of conductive TSVs include a plurality of different subsets of conductive TSVs; and
each of the subsets of conductive TSVs is vertically aligned with a respective one of the thermal hot spot regions.

5. The structure of claim 1, further comprising a first metallization structure disposed between the supporting substrate and the metallic lid structure, wherein the first metallization structure is thermally coupled to the conductive TSVs.

6. The structure of claim 5, further comprising:
a thermal interface material (TIM) disposed between the first metallization structure and the metallic lid structure; and
a second metallization structure disposed between the metallic lid structure and the TIM.

7. The structure of claim 6, wherein the TIM comprises a solder material.

8. The structure of claim 1, wherein the one or more top level IC dies include at least a first System on a Chip (SoC) die and a second SoC die.

9. The structure of claim 1, wherein the metallic lid structure includes a copper lid structure.

10. A structure, comprising:
one or more integrated circuit (IC) dies, wherein a first region of the one or more IC dies has a greater temperature than a second region of the one or more IC dies that neighbors the first region;
a substrate disposed over the one or more IC dies, wherein the substrate includes a plurality of through substrate vias (TSVs), and wherein a location of the TSVs is vertically aligned with a location of the first region of the one or more IC dies; and
a thermally conductive lid structure disposed over the substrate, wherein the thermally conductive lid structure is thermally coupled to the first region of the one or more IC dies at least in part through the TSVs.

11. The structure of claim 10, further comprising:
a metallization structure disposed between the substrate and the thermally conductive lid structure, wherein the metallization structure is in direct contact with the TSVs; and
a thermal interface material (TIM) disposed between the metallization structure and the thermally conductive lid structure.

12. The structure of claim 10, wherein the thermally conductive lid structure includes a single block of copper.

13. A method, comprising:
forming a first dielectric layer over a first side of an Integrated Circuit (IC) structure that includes one or more IC dies;
forming a plurality of first bonding pads that each extend vertically through the first dielectric layer;
bonding a supporting substrate to the first dielectric layer, wherein the supporting substrate includes a plurality of through substrate vias (TSVs), and wherein the bonding is performed such that the TSVs are thermally coupled to the first bonding pads, respectively;
reducing a thickness of the supporting substrate from the first side until the TSVs are exposed to the first side; and
attaching a metallic lid structure to the supporting substrate such that the metallic lid structure is thermally coupled to the TSVs.

14. The method of claim 13, wherein:
the IC structure includes one or more thermal hot spot regions; and
the bonding is performed such that each of the one or more thermal hot spot regions is vertically aligned with a respective subset of the TSVs.

15. The method of claim 13, further comprising, after the thickness of the supporting substrate has been reduced but before the metallic lid structure has been attached:
forming a first metallization structure over the supporting substrate, such that the TSVs are thermally coupled to the first metallization structure; and
forming a thermal interface material (TIM) over the first metallization structure, wherein the TIM is located between the first metallization structure and the metallic lid structure after the metallic lid structure has been attached.

16. The method of claim 15, wherein:
a second metallization structure is formed on a second side of the metallic lid structure opposite the first side; and
the attaching of the metallic lid structure includes attaching the second metallization structure to the TIM.

17. The method of claim 13, further comprising:
forming a second dielectric layer over the supporting substrate; and
forming a plurality of second bonding pads in the second dielectric layer;
wherein:
the second bonding pads are thermally coupled to the TSVs; and
the bonding is performed such that the first bonding pads are bonded to the second bonding pads.

18. The method of claim 13, wherein the IC structure includes electrical circuitry, and wherein the method further comprises: forming a plurality of conductive bumps over a second side of the IC structure opposite the first side, wherein the conductive bumps are electrically coupled to the electrical circuitry of the IC structure.

19. The method of claim 13, wherein:
the IC structure is a wafer level IC structure; and
the method further comprises singulating the wafer level IC structure before the metallic lid structure is attached.

20. The method of claim 13, wherein the IC structure includes a bottom IC die and one or more top IC dies that are electrically coupled to the bottom IC die.
